(19) United States
(12) Patent Application Publication
(10) Pub. No.: US 2018/0342507 A1
(43) Pub. Date: Nov. 29, 2018

(54) INTEGRATION OF VERTICAL-TRANSPORT TRANSISTORS AND HIGH-VOLTAGE TRANSISTORS

(71) Applicant: GLOBALFOUNDRIES Inc., Grand Cayman (KY)

(72) Inventors: Ruilong Xie, Niskayuna, NY (US); Chun-Chen Yeh, Danbury, CT (US); Kangguo Cheng, Schenectady, NY (US); Tenko Yamashita, Schenectady, NY (US)

(21) Appl. No.: 15/604,932

(22) Filed: May 25, 2017

(51) Int. Cl. H01L 27/088; H01L 29/66; H01L 29/40; H01L 29/417; H01L 29/51; H01L 29/78

(52) U.S. Cl. CPC H01L 27/0886; H01L 29/66666; H01L 29/7827; H01L 29/41741; H01L 29/517; H01L 29/401

(57) ABSTRACT

Methods and structures that include a vertical-transport field-effect transistor. A first section of a dielectric layer is deposited on a first device region of a substrate and a second section of the dielectric layer is deposited on a second device region of the substrate. A gate stack is deposited on the first device region and the second device region. The gate stack is patterned to define a first gate electrode of the vertical-transport field-effect transistor on the first section of the dielectric layer and a second gate electrode of a high-voltage field-effect transistor on the second section of the dielectric layer. The first section of the dielectric layer is a spacer layer arranged between the first gate electrode and the first device region. The second section of the dielectric layer is a portion of a gate dielectric arranged between the second gate electrode and the second device region.

### BACKGROUND

The present invention relates to semiconductor device fabrication and integrated circuits and, more specifically, to methods for forming a structure that includes vertical-transport field-effect transistors and structures that include vertical-transport field-effect transistors.

Device structures for a field-effect transistor generally include a body region, a source and a drain defined in the body region, and a gate electrode configured to switch carrier flow in a channel formed in the body region. When a control voltage exceeding a designated threshold voltage is applied to the gate electrode, carrier flow occurs in an inversion or depletion layer in the channel between the source and drain to produce a device output current. The body region and channel of a planar field-effect transistor are located beneath the top surface of a substrate on which the gate electrode is supported.

Planar field-effect transistors and fin-type field-effect transistors constitute a general category of transistor structures in which the direction of gated current in the channel is in a horizontal direction parallel to the substrate surface. In a vertical-transport field-effect transistor, the source and the drain are arranged at the top and bottom of a semiconductor fin or pillar. The direction of the gated current transport in the channel between the source and drain is generally perpendicular (i.e., vertical) to the substrate surface and parallel to the height of the semiconductor fin or pillar.

### SUMMARY

In an embodiment, a method is provided for forming a vertical-transport field-effect transistor using a first device region of a substrate and a high-voltage field-effect transistor using a second device region of the substrate. A semiconductor fin of the vertical-transport field-effect transistor is formed that projects from the first device region. A dielectric layer is deposited on the first device region and the second device region. After the dielectric layer is deposited, a gate stack is deposited on the first device region and the second device region. The gate stack is patterned to define a first gate electrode that is associated with the semiconductor fin in the first device region and a second gate electrode of the high-voltage field-effect transistor in the first device region. The dielectric layer is patterned to define a first section of the dielectric layer masked by the first gate electrode as a spacer layer arranged between the first gate electrode and the first device region. The dielectric layer is patterned to define a second section of the dielectric layer masked by the second gate electrode as a first portion of a gate dielectric arranged between the second gate electrode and the second device region.

In an embodiment, a structure is formed using a first device region and a second device region of a substrate. The structure includes a vertical-transport field-effect transistor and a high-voltage field-effect transistor. The vertical-transport field-effect transistor includes a semiconductor fin on the first device region, a first gate electrode associated with the semiconductor fin, and a spacer layer arranged between the first gate electrode and the first device region. The high-voltage field-effect transistor includes a second gate electrode and a gate dielectric between the second gate electrode and the second device region. The gate dielectric includes a first section of a first dielectric layer and a first section of a second dielectric layer stacked with the first section of the first dielectric layer. The spacer layer of the vertical-transport field-effect transistor is a second section of the first dielectric layer of the high-voltage field-effect transistor.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-7 are cross-sectional views showing a structure at successive fabrication stages of a processing method in accordance with embodiments of the invention.

FIG. 4A is a cross-sectional view taken along the length of the fin in FIG. 4.

### DETAILED DESCRIPTION

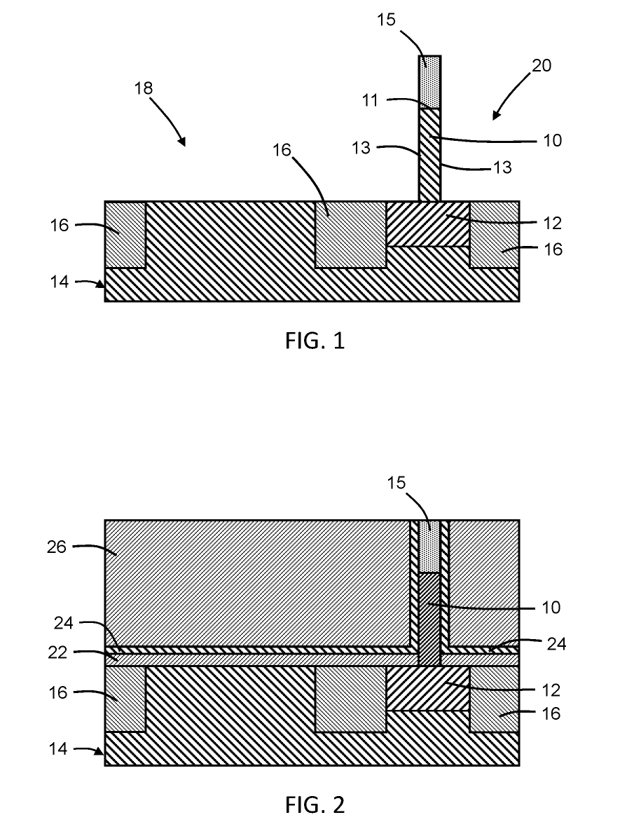

With reference to FIG. 1 and in accordance with an embodiment of the invention, a fin 10 projects in a vertical direction from a bottom source/drain region 12. The bottom source/drain region 12 may be a portion of a doped epitaxial layer at the top surface of a substrate 14. As used herein, the term “source/drain region” means a doped region of semiconductor material that can function as either a source or a drain of a vertical field-effect transistor. The substrate 14 beneath the bottom source/drain region 12 may be, for example, a bulk single-crystal silicon substrate. The fin 10 is used to form a vertical-transport field-effect transistor as described hereinbelow. Additional fins (not shown) may be located on the bottom source/drain region 12 adjacent to fin 10.

The fin 10 has a top surface 11 and one or more sidewalls 13 that extend in the vertical direction from the top surface 11 to intersect with the bottom source/drain region 12. The fin 10 may be formed from an epitaxial layer of semiconductor material, such as undoped or intrinsic silicon, that is grown on the bottom source/drain region 12 and patterned using photolithography and etching processes, such as a sidewall imaging transfer (SIT) process or self-aligned double patterning (SADP). The fin 10 may be capped by a section of a hardmask 15 associated with its patterning.

The bottom source/drain region 12 may be formed in a substrate by masked implantation before the epitaxial layer is grown to form the fin 10. Alternatively, the bottom source/drain region 12 may be formed after fin formation by forming a sacrificial layer on the fin 10, recessing the substrate adjacent to the fin 10, and epitaxially growing the bottom source/drain region 12 followed by removal of the sacrificial layer. In connection with the formation of an n-type vertical-transport field effect transistor, the bottom source/drain region 12 may be composed of silicon and include a concentration of an n-type dopant from Group V of the Periodic Table (e.g., phosphorus (P) and/or arsenic (As)) that is effective to impart n-type electrical conductivity to the constituent semiconductor material. In connection with the formation of a p-type vertical-transport field effect transistor, the bottom source/drain region 12 may be composed of a silicon-germanium (SiGe) alloy and include a concentration of p-type dopant from Group III of the Periodic Table (e.g., boron (B), aluminum (Al), gallium (Ga), and/or indium (In)) in a concentration that is effective to impart p-type electrical conductivity to the constituent semiconductor material.

Shallow trench isolation regions 16 are formed that penetrate to a shallow depth into the substrate 14. The shallow trench isolation regions 16 physically separate and electrically isolate a device region 18 from a device region 20 that includes the fin 10. The shallow trench isolation regions 16 may be composed of a dielectric material, such as an oxide of silicon (e.g., silicon dioxide (SiO₂)), deposited by chemical vapor deposition (CVD) and etched back to the top surface of the device regions 18, 20.

With reference to FIG. 2 in which like reference numerals refer to like features in FIG. 1 and at a subsequent fabrication stage, a bottom spacer layer 22 is formed on the bottom source/drain region 12 in device region 20, the device region 18, and the shallow trench isolation regions 16. The bottom spacer layer 22 may be composed of a dielectric material, such as silicon nitride (Si₃N₄) or silicon dioxide (SiO₂), that is deposited by a directional deposition technique, such as high-density plasma (HDP) deposition or gas cluster ion beam (GCIB) deposition. A lower portion of the fin 10 extends in the vertical direction through the thickness of the bottom spacer layer 22.

A gate dielectric layer 24 is conformally deposited on the sidewalls 13 of the fin 10 and on the bottom spacer layer 22. The gate dielectric layer 24 may be composed of a dielectric material, such as a high-k dielectric having a dielectric constant (e.g., permittivity) higher than the dielectric constant of SiO₂. Candidate high-k dielectric materials for the gate dielectric layer 24 include, but are not limited to, a hafnium-based dielectric material like hafnium oxide (HfO₂), a layered stack of a hafnium-based dielectric material and another other dielectric material (e.g., aluminum oxide (Al₂O₃)), or combinations of these and other dielectric materials.

A gate stack 26 is formed on the gate dielectric layer 24 and is planarized by, for example, chemical mechanical polishing (CMP) stopping on the hardmask 15 on the fin 10. The gate stack 26 may be composed of one or more conformal barrier metal layers and/or work function metal layers, such as titanium aluminum carbide (TiAlC), titanium nitride (TiN), cobalt (Co), tungsten (W), or combinations of these and other metals. The layers of gate stack 26 may be serially deposited by, for example, physical vapor deposition (PVD) or CVD.

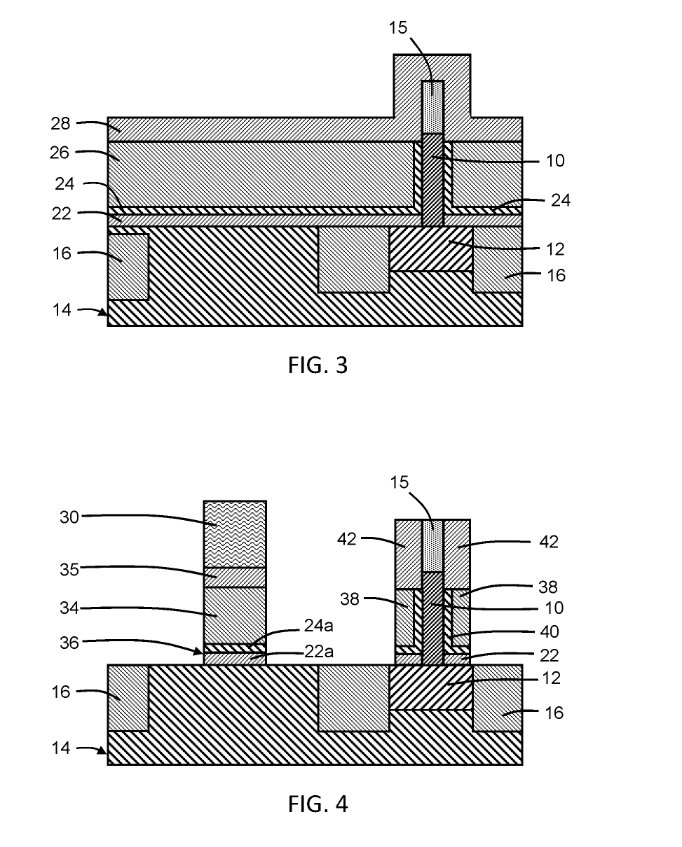

With reference to FIG. 3 in which like reference numerals refer to like features in FIG. 2 and at a subsequent fabrication stage, the gate stack 26 and the gate dielectric layer 24 are etched back and thereby recessed such that the hardmask 15 and an upper portion of the fin 10 project above the level of the top surface of the gate stack 26 and the gate dielectric layer is removed from this portion of the fin 10. The gate length of the vertical-transport field-effect transistor formed using the fin 10 and gate stack 26 is established by the etch back. A conformal dielectric layer 28 is deposited on the gate stack 26 and fin 10. The conformal dielectric layer 28 may be composed of a dielectric material, such as silicon oxycarbide (SiCO) or another type of low-k dielectric material.

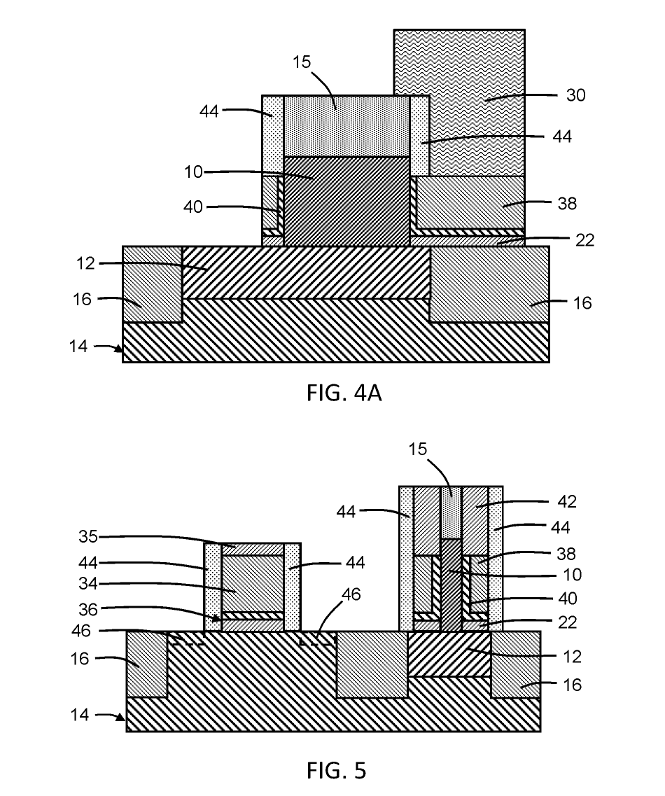

With reference to FIGS. 4, 4A in which like reference numerals refer to like features in FIG. 3 and at a subsequent fabrication stage, an etch mask 30 is applied that includes a feature aligned with a section of the gate stack 26 in device region 18. Etching processes, such as reactive ion etching (RIE) processes, may be used to directionally etch the conformal dielectric layer 28, the gate stack 26, the gate dielectric layer 24, and the bottom spacer layer 22 to define a gate electrode 34 and a gate dielectric 36 at the location of the feature in the etch mask 30. Each of these etching processes may rely on a given etch chemistry selected according to the material being etched. The gate electrode 34 includes a dielectric cap 35 from the etched conformal dielectric layer 28. The gate dielectric 36 that includes contributions from a section 24a of the dielectric material of the gate dielectric layer 24 and a section 22a of the dielectric material of the bottom spacer layer 22. The gate electrode 34 and gate dielectric 36 furnish structural elements of a high-voltage planar transistor in which the gate electrode 34 is a metal gate and the gate dielectric 36 is a composite structure. The gate dielectric 36 has a dielectric constant that is equal to a composite of the dielectric constants of the material of the gate dielectric layer 24 and the material of the bottom spacer layer 22, and that is appropriate for a high-voltage planar transistor.

In device region 20, a directional etch process etches the material of the conformal dielectric layer 28 to form a top spacer layer 42, followed by directional etching processes that etch the gate stack 26, the gate dielectric layer 24, and the bottom spacer layer 22 selective to the material of the top spacer layer 42. A gate electrode 38 of a vertical-transport field-effect transistor is defined by the etching of the gate stack 26, and a gate dielectric 40 is defined by the etching of the gate dielectric layer 24. The gate electrode 38 is separated from the fin 10 by the gate dielectric 40. As best shown in FIG. 4A, a portion of the etch mask 30 covers a portion of the gate stack 26 that is masked and preserved during the etching processes in order to later provide a landing area for a gate contact to the gate electrode 38.

With reference to FIG. 5 in which like reference numerals refer to like features in FIG. 4 and at a subsequent fabrication stage, the etch mask 30 is stripped, and sidewall spacers 44 are formed by depositing a conformal layer comprised of a dielectric material, such as silicon nitride (Si₃N₄), and shaping the conformal layer with an anisotropic etching process, such as reactive ion etching (RIE). The anisotropic etching process preferentially removes the dielectric material from horizontal surfaces in deference to the dielectric material remaining adjacent to vertical surfaces as sidewall spacers 44.

Source/drain regions 46 may be formed by ion implantation in device region 18 with the gate electrode 34 and sidewall spacers 44 providing masking for self-alignment. The ions may be generated from a suitable source gas and implanted into the device region 18 with selected implantation conditions (e.g., ion species, dose, kinetic energy) using an ion implantation tool. The source/drain regions 46 may be doped with a concentration of a p-type dopant or with a concentration of an n-type dopant depending on the type of high-voltage field-effect transistor being formed.

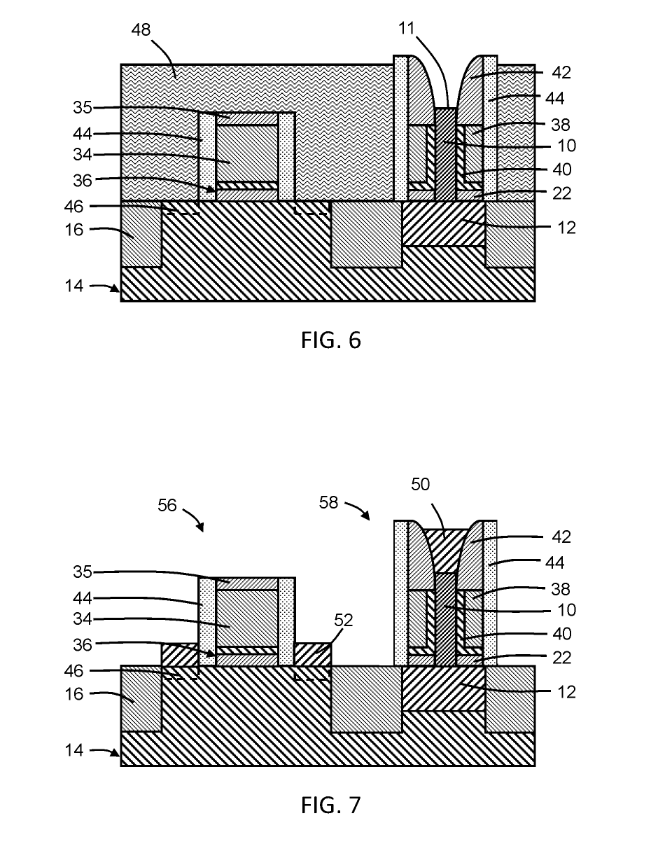

With reference to FIG. 6 in which like reference numerals refer to like features in FIG. 5 and at a subsequent fabrication stage, a sacrificial layer 48 is applied to fill open gaps in the device regions 18, 20. The sacrificial layer 48 may be comprised of, for example, an organic planarization layer (OPL) material or another spin-on material applied by spin coating. The sacrificial layer 48 is etched back to expose the hardmask 15 on the top surface 11 of the fin 10. The partially-completed high-voltage field-effect transistor is buried within the sacrificial layer 48. The hardmask 15 is removed from the fin 10 with an etching process, such as RIE, to reveal the top surface 11 of the fin 10. The shape of the top spacer layer 42 bordering the opened space may be altered by the etching process removing the hardmask 15.

With reference to FIG. 7 in which like reference numerals refer to like features in FIG. 6 and at a subsequent fabrication stage, the sacrificial layer 48 is stripped by, for example, ashing with an oxygen plasma. A top source/drain region 50 is formed on the top surface 11 of the fin 10 that are exposed through the top spacer layer 42. The top source/drain region 50 may be composed of semiconductor material that is doped to have the same conductivity type as the bottom source/drain region 12. If the bottom source/drain region 12 is n-type, then the top source/drain region 50 may be a section of an epitaxial layer of semiconductor material formed by an epitaxial growth process with in-situ doping, and may include a concentration of an n-type dopant from Group V of the Periodic Table (e.g., phosphorus (P) and/or arsenic (As)) that is effective to impart n-type electrical conductivity to the constituent semiconductor material. If the bottom source/drain region 12 is p-type, then the top source/drain region 50 may be a section of an epitaxial layer of semiconductor material formed by an epitaxial growth process with in-situ doping, and may include a concentration of a p-type dopant from Group III of the Periodic Table (e.g., boron (B), aluminum (Al), gallium (Ga), and/or indium (In)) that is effective to impart p-type electrical conductivity to the constituent semiconductor material. In an embodiment, the top source/drain region 50 may be formed by a selective epitaxial growth (SEG) process in which semiconductor material nucleates for epitaxial growth on semiconductor surfaces (e.g., fin 10), but does not nucleate for epitaxial growth from insulator surfaces (e.g., shallow trench isolation regions 16).

Raised source/drain regions 52 are formed by the epitaxial growth process on the source/drain regions 46 that were previously formed by ion implantation in device region 18. The gate electrode 34 and sidewall spacers 44 may provide masking for self-aligned growth of the raised source/drain regions 52.

The resulting structure includes a high-voltage field-effect transistor 56 in device region 18 and a vertical-transport field-effect transistor 58 in device region 20. The high-voltage field-effect transistor 56 is a planar device structure that includes the gate electrode 34, the gate dielectric 36, the source/drain regions 46 in the substrate 14, and the raised source/drain regions 52. The gate dielectric is a composite of the dielectric materials from the gate dielectric layer 24 and the bottom spacer layer 22, and is characterized by a high breakdown voltage needed for a high-voltage transistor handling voltages in a range of 200 volts to 1000 volts. During operation, a horizontal channel is defined in the device region 18 beneath the gate electrode 34.

The vertical-transport field-effect transistor 58 includes the fin 10, the bottom source/drain region 12, the top source/drain region 50, the gate electrode 38, and the gate dielectric 40. The gate electrode 38 is arranged along the height of the fin 10 in the vertical direction between the bottom source/drain region 12 and the top source/drain region 50. During operation, a vertical channel for carrier transport is defined in a portion of the fin 10 overlapped by the gate electrode 38 between the bottom source/drain region 12 and the top source/drain region 50.

Middle-of-line (MOL) and back-end-of-line (BEOL) processing follow, which includes formation of contacts and wiring for the local interconnect structure overlying the the high-voltage field-effect transistor 56 and the vertical-transport field-effect transistor, and formation of dielectric layers, via plugs, and wiring for an interconnect structure coupled by the interconnect wiring with the gate electrodes and source/drain regions of the high-voltage field-effect transistor 56 and the vertical-transport field-effect transistor 58.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, “lateral”, etc. are made by way of example, and not by way of limitation, to establish a frame of reference. Terms such as “horizontal” and “lateral” refer to a direction in a plane parallel to a top surface of a semiconductor substrate, regardless of its actual three-dimensional spatial orientation. Terms such as “vertical” and “normal” refer to a direction perpendicular to the “horizontal” and “lateral” direction. Terms such as “above” and “below” indicate positioning of elements or structures relative to each other and/or to the top surface of the semiconductor substrate as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for forming a vertical-transport field-effect transistor using a first device region of a substrate and a high-voltage field-effect transistor using a second device region of the substrate, the method comprising:
forming a semiconductor fin of the vertical-transport field-effect transistor that projects from the first device region;
depositing a first dielectric layer on the first device region and the second device region;
after the first dielectric layer is deposited, depositing a gate stack on the first device region and the second device region;
etching the gate stack to define a first gate electrode that is associated with the semiconductor fin in the first device region and a second gate electrode of the high-voltage field-effect transistor in the first device region;
patterning the first dielectric layer to define a first section of the first dielectric layer masked by the first gate electrode as a spacer layer arranged between the first gate electrode and the first device region; and
patterning the first dielectric layer to define a second section of the first dielectric layer masked by the second gate electrode as a first portion of a gate dielectric arranged between the second gate electrode and the second device region.

2. The method of claim 1 wherein the first device region includes a first source/drain region of the vertical-transport field-effect transistor, and further comprising:
after the gate stack is etched, epitaxially growing a second source/drain region of the vertical-transport field-effect transistor on the semiconductor fin,
wherein the first gate electrode is arranged in a vertical direction between the first source/drain region and the second source/drain region.

3. The method of claim 2 wherein the second source/drain region is epitaxially grown by a growth process, and further comprising:
epitaxially growing, with the growth process, a source/drain region of the high-voltage field-effect transistor on the second device region adjacent to the second gate electrode.

4. The method of claim 1 further comprising:
before the gate stack is deposited, depositing a gate dielectric layer on the first device region and on the second device region; and
after the gate stack is etched, etching the gate dielectric layer to define a gate dielectric of the vertical-transport field-effect transistor and a second portion of the gate dielectric of the high-voltage field-effect transistor.

5. The method of claim 4 wherein the first dielectric layer is formed before the gate dielectric layer.

6. The method of claim 4 wherein the gate dielectric layer is comprised of a high-k dielectric material, and the first dielectric layer is comprised of silicon nitride or silicon dioxide.

7. The method of claim 1 comprising:
before the gate stack is etched, applying an etch mask on the second device region with a feature that masks a section of the gate stack that is etched to define the second gate electrode.

8. The method of claim 7 wherein the first device region includes a first source/drain region of the vertical-transport field-effect transistor, and further comprising:
before the gate stack is deposited, forming a semiconductor fin on the first source/drain region;
before the gate stack is etched, recessing the gate stack to reveal a portion of the semiconductor fin;
after the gate stack is recessed, conformally depositing a second dielectric layer on the gate stack and the portion of the semiconductor fin; and
etching the second dielectric layer to form a top spacer layer on the gate stack,
wherein the top spacer layer masks the gate stack when the gate stack is etched to define the first gate electrode.

9. The method of claim 1 comprising:
after the gate stack is etched, conformally depositing a second dielectric layer; and
etching the second dielectric layer to concurrently define a first sidewall spacer on the first gate electrode and a second sidewall spacer on the second gate electrode.

10. A structure formed using a first device region and a second device region of a substrate, the structure comprising:
a vertical-transport field-effect transistor including a semiconductor fin on the first device region, a first gate electrode associated with the semiconductor fin, and a spacer layer arranged between the first gate electrode and the first device region; and
a high-voltage field-effect transistor including a second gate electrode and a gate dielectric between the second gate electrode and the second device region, the gate dielectric including a first section of a first dielectric layer and a first section of a second dielectric layer stacked with the first section of the first dielectric layer,
wherein the spacer layer is a second section of the first dielectric layer, the spacer layer is in direct contact with the first device region, and the second dielectric layer includes a layer stack containing a plurality of dielectric materials.

11. The structure of claim 10 wherein a second section of the second dielectric layer is arranged between the first gate electrode and the semiconductor fin.

12. The structure of claim 11 wherein the first section of the first dielectric layer and the second section of the first dielectric layer have a first equal thickness, and the first section of the second dielectric layer and the second section of the second dielectric layer have a second equal thickness.

13. The structure of claim 11 wherein the first dielectric layer is comprised of silicon nitride or silicon dioxide, and the second dielectric layer is comprised of a high-k dielectric material.

14. The structure of claim 10 wherein the first section of the first dielectric layer and the second section of the first dielectric layer have an equal thickness.

15. The structure of claim 10 wherein the first dielectric layer is comprised of silicon nitride or silicon dioxide, and the second dielectric layer is comprised of a high-k dielectric material.

16. The structure of claim 10 wherein the first section of the first dielectric layer is arranged between the first section of the second dielectric layer and the second device region.

17. The structure of claim 16 wherein a second section of the second dielectric layer is arranged between the first gate electrode and the semiconductor fin.

18. The structure of claim 16 wherein the first dielectric layer is comprised of silicon nitride or silicon dioxide, and the second dielectric layer is comprised of a high-k dielectric material.

19. The structure of claim 10 wherein the vertical-transport field-effect transistor includes a first source/drain region in the first device region and a second source/drain region on the semiconductor fin, and the first gate electrode is arranged in a vertical direction between the first source/drain region and the second source/drain region.

20. The structure of claim 19 wherein the high-voltage field-effect transistor includes a source/drain region on the second device region adjacent to the second gate electrode, the raised source/drain region is a first section of a semiconductor layer, and the second source/drain region is a second section of the semiconductor layer.
